(19) United States
(12) Patent Application Publication
(10) Pub. No.: US 2008/0194086 A1
(43) Pub. Date: Aug. 14, 2008

(54) Method of Introducing Impurity

(76) Inventors: Yuichiro Sasaki, Tokyo (JP); Bunji Mizuno, Nara (JP); Katsumi Okashita, Tokyo (JP); Cheng-Guo Jin, Osaka (JP); Hiroyuki Ito, Chiba (JP)

Correspondence Address: MCDERMOTT WILL & EMERY LLP, 600 13TH STREET, N.W., WASHINGTON, DC, 20005-3096, US

(21) Appl. No.: 11/628,454

(22) PCT Filed: May 31, 2005
(86) PCT No.: PCT/JP05/09949

§ 371 Date: Oct. 29, 2007

(30) Foreign Application Priority Data
Jun. 4, 2004 (JP) 2004-167786

(51) Int. Cl. H01L 21/26; H01L 21/265

(52) U.S. Cl. 438/513; 438/518; 257/E21.211

(57) ABSTRACT

There is provided a method of introducing impurity capable of efficiently realizing a shallow impurity introduction. The impurity introducing method includes a first step of making a surface of a semiconductor layer to be amorphous by reacting plasma composed of particles which are electrically inactive in the semiconductor layer to a surface of a solid base body including the semiconductor layer, and a second step of introducing impurity to the surface of the solid base body.

After performing the first step, by performing the second step, an amorphous layer with fine pores is formed on the surface of the solid base body including the semiconductor layer, and impurity are introduced in the amorphous layer to form an impurity introducing layer.

### TECHNICAL FIELD

The present invention relates to a method of introducing impurity, and more particularly, to a method of introducing the impurity in the course of manufacturing semiconductor devices or the like.

### BACKGROUND ART

As the result of recent development in finer device technologies in the device sector, it is requested to form a junction in a shallower profile. The low-energy ion implantation is known as a technology used for forming a shallow junction. The low-energy ion implantation technique is a method of pulling ions out of an ion source with a substantially high voltage and decelerating them at a latter stage. In this way, a low-energy implantation is realized while keeping the beam current value at a substantially high level. Such technologies have been successful in providing impurity layers in a profile as shallow as several 10 nm; and the layers have been in practical use in the semiconductor device industry.

Plasma doping technology is attracting the attention as a new technology for forming the junction in a still shallower profile. The plasma-doping technique is a technique for introducing impurities into a surface of an object to be processed (e.g., semiconductor substrate) by contacting plasma including desired particles with the surface of the object to be processed. Since the energy of plasma is as low as several hundreds volts at the highest, it is a suitable vehicle for forming an impurity layer in a shallow profile. According to experimental reports, the shallow junctions of ten-odd nm to a depth of several 10 nm have been formed.

Non-Patent Document 1 discloses an experimental result achieving the shallowest P-type junction; according to which, the junction depth is 7 nm.

Gaseous phase doping method which uses a gas source is also disclosed in (1) Non-Patent Document 2, (2) Non-Patent Document 3, (3) Non-Patent Document 4 and other publications. According to the method, a semiconductor substrate is heated in the normal pressure atmosphere of hydrogen, and B₂H₆, PH₃ are supplied thereto for providing impurity diffusion layers, P-type and N-type. The hydrogen carrier gas is effective for removing the natural oxidation film sticking on the silicon surface, and for keeping the surface clean. Therefore, it is advantageous in suppressing a surface segregation of the impurity, particularly boron.

For decomposing the gas, it requires a high temperature, generally higher than 600° C. Non-Patent Document 5, for example, reports an experimental result of forming a high-concentration shallow junction, in which a semiconductor substrate is heated to 900° C. and B₂H₆ gas of 1 ppm is delivered for 40 seconds. According to this experimental result, a depth that boron concentration becomes 1*10¹⁸ cm⁻³ is defined as a depth of a junction, and the depth of the junction is approximately 7 nm which is the same level as that described above.

Further, Non-Patent Document 6 discloses a technology that the vapor-phase doping methods are executed at room temperature. These are methods that when material is introduced into a solid base body where a film such as an oxide adheres to its surface, desired particles are stuck or introduced after removing the film such as the oxide. According to the report, a depth of an impurity-introducing layer is 3 to 4 nm.

As discussed above, by using the plasma-doping technique or the low-energy ion implantation technique, the experiments for forming shallow junctions of over 10 nm to several 10 nm have been recently reported. The current experiment achieving the shallowest P-type junction forms a shallow impurity layer of approximately 7 nm. However, according to further miniaturization of devices, a method of forming shallower impurity layers more simply with low resistance is required.

As a technology for meeting the need mentioned above, since the plasma-doping technique can introduce particles into a semiconductor substrate with small accelerating energy, the plasma-doping technique can form introducing layers shallower than the ion implantation technique. However, though it is small energy, it has accelerating energy, so that there is a limit to form shallower. In addition, the plasma-doping is known that a radical is supplied to a substrate as dopant. Since a radical does not have an electric charge, it is not accelerated and struck into the substrate. However, it is thought that since it is active, it reacts to a surface of the substrate and is introduced into the substrate. The vapor-phase doping method using a gas source is a technology that an impurity-diffusion layer is formed by supplying dopant, which does not have accelerating energy, into the substrate and reacting with its surface. These are positioned as a technology exceeding limit in the method of irradiating ions having energy onto the substrate.

For example, a method of ion-implanting germanium or silicon is known as a technology for making crystal silicon of the semiconductor substrate amorphous. A process for ion-implanting germanium or silicon into a silicon substrate and making its surface amorphous, then ion-implanting impurity such as boron, and then annealing is widely used. The following advantages of making amorphous before ion-implanting impurity are known:

(1) Small impurity such as boron are difficult to be introduced deeply in ion-implanting; and (2) Impurity can be activated efficiently in annealing since amorphous silicon has a higher absorption coefficient of light than crystal silicon.

However, amorphism by using ion-implanting has a problem in that it has insufficient precision for forming a shallow amorphous layer and a narrow range of annealing condition for recovering the silicon crystal after the annealing.

To the contrary, recently, there is disclosed a technology for making the surface of a silicon substrate to be amorphous by irradiating plasma to the silicon substrate, which is performed as a pre-process for the impurity introduction. In Non-Patent Document 7, the present inventor has discloses a technology for introducing boron as impurity after forming an amorphous layer of 4.3 nm thickness by irradiating argon plasma to the silicon substrate. Moreover, Non-Patent Document 8 discloses a result of forming a damage-rich layer of 25 nm thickness by irradiating hydrogen plasma to the silicon substrate. In the above-mentioned technology, it is reported that the damage-rich layer was recovered at a low temperature by performing the annealing at 300° C. for 5 minutes.

Meanwhile, a method of using helium plasma is known as a technology for reforming the surface of the silicon substrate by irradiating plasma to the silicon substrate. Non-Patent Document 9 discloses a technology for forming pores inside the silicon substrate by irradiating the helium plasma to the silicon substrate. According to this technology, it is reported that pores having a diameter of between 8 nm and 50 nm were formed to a depth range of between 50 nm and 250 nm from the surface of the silicon substrate by irradiating the helium plasma to the silicon substrate. A bias voltage of 8 keV or 20 keV was applied to the plasma. In addition, the document also discloses a cross-sectional TEM photograph of the pores formed to a depth range of between 20 nm and 100 nm. The document also discloses the pores having a diameter of 16 nm or 20 mm.

Followings are the above-mentioned examples of related art:

Non-Patent Document 1: Technical Digest of Symposium on VLSI Technology, Honolulu, P.110 (2000));

Non-Patent Document 2: International Workshop on Junction Technology (IWJT), P.19 (2000);

Non-Patent Document 3: J. Vac. Sci. Technol. A16, P.1 (1998);

Non-Patent Document 4: Silicon Technology (No. 39 18 Jun., 2002);

Non-Patent Document 5: Silicon Technology (No. 39, 18 Jun., 2002);

Non-Patent Document 6: International Workshop on Junction Technology (IWJT), p. 39-40 (2000);

Non-Patent Document 7: International Workshop on Junction Technology (IWJT), p. 46-49 (2000);

Non-Patent Document 8: International Workshop on Junction Technology (IWJT), p. 54-57 (2000); and

Non-Patent Document 9: Handbook of Plasma Immersion Ion Implantation and Deposition, p. 663-666.

### DISCLOSURE OF THE INVENTION

### Problem that the Invention is to Solve

According to the methods known in the art, it is difficult to form the shallow junction with high precision.

Therefore, the invention provides a technology for efficiently introducing impurity to a small depth.

### Means for Solving the Problem

A method of introducing impurity according to the invention is characterized in that the method includes a first step of making a surface of a semiconductor layer to be amorphous by reacting plasma composed of particles which are electrically inactive in the semiconductor layer to a surface of a solid base body including the semiconductor layer; and a second step of introducing impurity to the surface of the solid base body.

According to the above method, when introducing the impurity, the plasma irradiation condition is controlled so as to suppress the formation of a damage layer, and a shallow amorphous layer having good optical absorption characteristics is easily prepared by the inactive plasma without having influence on the semiconductor characteristics. Moreover, since the elements introduced into a silicon substrate from the plasma are effectively diffused outward by an annealing process, it is possible to recover crystallinity.

The method of introducing impurity according to the invention is characterized in that the first step includes a step of irradiating the plasma to the surface of the semiconductor layer.

According to the above method, it is possible to efficiently realize the amorphism by irradiating inactive plasma. Since the plasma is inactive, the plasma is unlikely to react with the silicon substrate. Therefore, it is possible to reduce or suppress electrical influence. Since radical is hardly formed in the plasma, the plasma rarely reacts with elements constituting the solid base body such as silicon. Moreover, it is advantageous in reducing an etching rate even though it depends on the type of elements.

The method of introducing impurity according to the invention is characterized in that the first step includes a step of irradiating ions to the surface of the semiconductor layer by introducing the plasma to the surface of the semiconductor layer through a mesh.

According to the above method, by irradiating plasma to the surface of the semiconductor layer through a mesh having a predetermined electric potential, a distributed ion irradiation known as an ion shower, is performed. Thus, it is possible to efficiently realize the amorphism. In the above method, since an ionic mass spectrometry is not performed, the amount of ion beam current irradiated to the solid base body is small compared with a direct plasma doping method but is much greater than that of an ion implanting method. Therefore, it is possible to efficiently realize the amorphism even with an element having relatively small atomic weight. For example, it may be possible to realize the amorphism event with an element such as helium or hydrogen having relatively small atomic weight.

The method of introducing impurity according to the invention is characterized in that after performing the first step, by performing the second step, an amorphous layer with fine pores is formed on the surface of the solid base body including the semiconductor layer, and impurity are introduced in the amorphous layer to form an impurity introducing layer.

According to the above method, since the impurity is selectively introduced into the pores, it is possible to narrow an impurity introducing region, i.e., a region where the impurity is trapped. Therefore, since it is possible to reduce abrupt difference in the impurity concentration between a region with pores and a region without pores, it is possible to increase the steepness of the impurity concentration in a depth direction. In other words, it is possible to abruptly change the impurity concentration in the vicinity of an interface of pn-junction, for example.

The method of introducing impurity according to the invention is characterized in that after performing the second step, by performing the first step, impurity are introduced to the surface of the solid base body including the semiconductor layer to form an impurity introducing layer, and the plasma composed of particles which are electrically inactive in the semiconductor layer is irradiated to the impurity introducing layer to form an amorphous layer.

According to the above method, similar to the above-mentioned method, since the impurity is selectively introduced into the pores, it is possible to narrow an impurity introducing region, i.e., a region where the impurity is trapped. Therefore, since it is possible to reduce abrupt difference in the impurity concentration between a region with pores and a region without pores, it is possible to increase the steepness of the impurity concentration in a depth direction.

The method of introducing impurity according to the invention is characterized in that the second step is performed simultaneously with the first step.

According to the above method, it is possible to determine the depth of introduced impurity and the depth of the amorphous layer in a single process. The depth of introduced impurity and the depth of the amorphous layer can be controlled by a bias voltage applied to the solid base body. However, when the first and second steps are separately performed, the depth of introduced impurity and the depth of the amorphous layer are influenced by the bias voltage applied in the respective step. In other words, the depth of introduced impurity varies with the depth of the amorphous layer. Moreover, in many cases, the depth of the amorphous layer increases in the process of introducing the impurity, even though there may be some difference in extent. In particular, when the depth of a preformed amorphous layer is small and it is desired to introduce the impurity to the silicon substrate having shallow amorphous layer, the depth of the amorphous layer becomes deeper than the original depth in the process of introducing the impurity. When the second step is performed simultaneously with the first step, since it is possible to determine the depth of introduced impurity and the depth of the amorphous-layer in a single process, it is easily controlled. Further, since it is possible to eliminate one step, it becomes efficient.

The method of introducing impurity according to the invention is characterized in that the electrically inactive plasma is helium plasma.

According to the above method, it is particularly easy to form pores in the semiconductor layer such as silicon. This is a peculiar characteristic of the helium plasma. Since helium element is easily diffused toward the outside of the semiconductor substrate in the annealing process and does not remain in the semiconductor substrate after the annealing, it is easy to recover crystallinity of silicon.

The method of introducing impurity according to the invention is characterized in that in the second step, plasma in which those impurities electrically active in the semiconductor layer are diluted with helium is irradiated to the surface of the solid base body.

According to the above method, since the second step is performed simultaneously with the first step, it is possible to reduce the number of processes. Moreover, similar to the above-mentioned method, since it is possible to determine the depth of introduced impurity and the depth of the amorphous layer in a single process, it is easily controlled. In the above method, the impurity used in the plasma is severely diluted with helium. Therefore, since the helium is easily diffused toward the outside of the semiconductor substrate and the crystallinity of the semiconductor is easily recovered, it is possible to form an impurity region hating good crystallinity. Moreover, when helium is mixed with another element, since pores having a great diameter are hardly formed in the silicon substrate, it is possible to decrease the sheet resistance which is usually unlikely to decrease. Alternatively, without forming pores in the silicon substrate by mixing another element with helium, it may be possible to realize the process which is advantageous in that the helium is easily diffused outward and it is thus possible to form an amorphous layer having good crystallinity recovering characteristics.

The method of introducing impurity according to the invention is characterized in that the first step is a step of forming an amorphous layer having fine pores which are smaller than 20 nm in diameter.

According to the above method, it is possible to prevent the sheet resistance from being influenced by the fact that the pores are so great that the semiconductor crystals are not recovered after the annealing. Therefore, it is desirable to adjust the diameter of the pores to a suitable size.

The method of introducing impurity according to the invention is characterized in that the diameter of the pores is smaller than 8 nm.

According to the above method, it is proven that the sheet resistance has been decreased after the annealing. When the diameter of the pores is smaller than 8 nm, the silicon crystal is more easily recovered and it is thus desirable.

The method of introducing impurity according to the invention is characterized in that the method further comprises an annealing step after the first step and the second step, wherein the annealing step is a step of electrically activating the impurity.

According to the above method, it is possible to electrically activate the impurity by effectively absorbing light during the annealing. As a result, it is possible to form a low-resistance layer in a further shallow profile. When there are pores, since the pores are in the amorphous layer, heat is effectively generated in the vicinity of the amorphous layer. Therefore, it is also possible to electrically activate the impurity trapped in the pores. As a result, it is possible to form a low-resistance layer in a further shallow and steep profile.

The method of introducing impurity according to the invention is characterized in that the first step is a step of forming an amorphous layer to a depth of 19 nm or less.

The method of introducing impurity according to the invention is characterized in that the first step is a step of forming an amorphous layer to a depth of 5 nm or more.

According to the above method, it is easy to form an amorphous layer having good optical absorption characteristics while suppressing surface roughness to a range where the surface roughness is not influenced by the depth of the amorphous layer. When the depth of the amorphous layer is smaller than 5 nm, optical absorption rate in the amorphous layer during the annealing decreases and thus it becomes difficult to decrease resistance. Meanwhile, when the depth of the amorphous layer is greater than 19 nm, the surface is roughened by the plasma irradiation and thus it may have influence on semiconductor devices.

The method of introducing impurity according to the invention is characterized in that the second step is a step of plasma-doping the impurity.

According to the above method, since it is possible to realize a very shallow impurity introduction with high throughput, it is more desirable.

The method of introducing impurity according to the invention is characterized in that the second step is a step of supplying impurity ions from the plasma through the mesh.

According to the above method, since it is possible to realize a very shallow impurity introduction with higher throughput compared with the case of using ion implantation, it is more desirable. Moreover, since only ions are extracted and irradiated to the solid base body, the solid main body does not react with radicals. Therefore, it is advantageous in that sputtering is not performed in such a manner that radicals contained in the plasma react with elements constituting the solid base body.

The method of introducing impurity according to the invention is characterized in that the second step is a step of ion-implanting the impurity.

According to the above method, since such a method has been widely used in the semiconductor industry, it is possible to realize a highly reliable impurity introduction.

The method of introducing impurity according to the invention is characterized in that the second step is a step of gas-doping the impurity.

According to the above method, it is possible to realize an impurity introduction with impurities having substantially no acceleration energy and form an impurity introduction layer in a shallower profile compared with the case of using plasma doping.

The method of introducing impurity according to the invention is characterized in that the first and second steps are performed in the same process chamber as a sequential process in-situ.

According to the above method, it is possible to reduce the effect of a natural oxide film on the second step. In general, as the thickness of the natural oxide film increases, the dose amount of the impurity applied in the second step is likely to decrease. In particular, when it is desired to introduce the impurity with low energy in order to form a shallow impurity introduction layer, the amount of impurity introduction decreases as the thickness of the natural oxide film increases. When the first and second steps are performed in the same process chamber as a sequential process in-situ, the thickness of the natural oxide film becomes smaller after the first step. In other words, the natural oxide film may not be found after the first step, or the natural oxide film becomes so thin that it can be ignored. Moreover, since the first and second steps are performed in a vacuum condition, the natural oxide film is rarely formed during between the first step and the second step. Therefore, it is possible to reduce the effect of a natural oxide film on the second step. Moreover, it is possible to eliminate burdens, such as incurred by transferring or maintaining the semiconductor substrate during the first and second steps.

The method of introducing impurity according to the invention is characterized in that the solid base body is silicon and the first step is a step of controlling the thickness of the amorphous layer by changing at least one condition of a bias voltage, an irradiating time, a bias power and a sheath voltage related to the plasma to be irradiated to the surface of the solid base body.

According to the above method, since it is possible to change the accelerating energy of plasma ions colliding with the solid base body by changing the bias voltage, the bias power and sheath voltage, it is possible to change the thickness of the amorphous layer. Even in the same accelerating energy of plasma ions colliding with the solid base body, it is possible to change the thickness of the amorphous layer to some extent by changing the ion colliding time with the solid base body.

The method of introducing impurity according to the invention is characterized in that the first step includes a step of irradiating the plasma composed of at least one element of the rare gas.

According to the above method, since the plasma is composed of inactive elements, it is possible to realize the plasma irradiation while decreasing the electric effect on the semiconductor. Moreover, since the plasma is composed of inactive elements, the elements in the plasma are unlikely to react with silicon within the semiconductor substrate even in the process of plasma irradiation. Therefore, etching rate is maintained at a low level during the plasma irradiation and thus it is desirable. Further, since the rare gas is chemically stable, it rarely reacts with the surface of the solid base body including silicon and thus it is rarely absorbed and attached to the solid base body. Therefore, in addition to the impurity introduction by ion, the impurity introduction by gas adsorption is expected.

The method of introducing impurity according to the invention is characterized in that the first step includes a step of irradiating the plasma including helium (He).

According to the above method, since helium element is likely to be diffused toward the outside of the semiconductor substrate in the annealing process and does not remain in the semiconductor substrate after the annealing, the silicon crystal is easily recovered and it is thus desirable. Moreover, since the atomic radius of helium element is smaller than that of silicon or germanium, it rarely hinders the recovery of crystals even when a little amount of helium element remains in the silicon and it is thus desirable. Moreover, since helium is an inactive element, it is unlikely to react with silicon within the semiconductor substrate even in the process of plasma irradiation. Therefore, etching rate is maintained at a low level during the plasma irradiation and thus it is desirable.

The method of introducing impurity according to the invention is characterized in that the first step is performed simultaneously with the second step and the first step includes a step of irradiating the plasma including helium gas having a concentration range of between 99% and 99.999%.

According to the above method, the method can be applied to the case where it is desired to form n-layer by introducing arsenic instead of boron. In other words, in the above method, gas containing impurity element such as arsenic is diluted with helium gas. According to the above method, it is possible to form n-layer by introducing an impurity such as arsenic by the dose amount that is generally used in ion implantation. Moreover, since helium is used in the formation of the amorphous layer, the helium element is likely to be diffused toward the outside of the semiconductor substrate in the annealing process and does not remain in the semiconductor substrate after the annealing. Therefore, the silicon crystal is easily recovered. Moreover, since the atomic radius of helium element is smaller than that of silicon or germanium, it rarely hinders the recovery of crystals even when a little amount of helium element remains in the silicon. Moreover, since helium is an inactive element, it is unlikely to react with silicon within the semiconductor substrate even in the process of plasma irradiation. Therefore, etching rate is maintained at a low level during the plasma irradiation.

In addition, it has been found that it is possible to select the depth of the amorphous layer by selecting the type of gas. Therefore, it is possible to select the type of gas on the basis of the desired depth of the amorphous layer. By selecting the type of gas on the basis of the depth of the amorphous layer, it is possible to for the amorphous layer to a desired depth without increasing the size of the apparatus or the load applied to the apparatus, The method of introducing impurity according to the invention is characterized in that the first step includes a step of irradiating the plasma including neon (Ne).

According to the above method, it is expected from the experimental result that it is possible to form the amorphous layer to a depth range of between 3.7 nm and 7.7 nm. Therefore, by selecting the type of gas, it is possible to efficiently form the impurity region to a desired depth. Moreover, since the atomic radius of Ne is smaller than that of silicon or germanium, it rarely hinders the recovery of crystals even when a little amount of Ne remains in the silicon and it is thus desirable.

The method of introducing impurity according to the invention is characterized in that the first step includes a step of irradiating the plasma including argon (Ar).

According to the above method, it is expected from the experimental result that it is possible to form the amorphous layer to a depth range of between 2 nm and 4.7 nm. Therefore, it is possible to efficiently form the impurity region to a desired depth. Moreover, since the atomic radius of Ar is smaller than that of germanium, it rarely hinders the recovery of crystals even when a little amount of Ar remains in the silicon compared with germanium and it is thus desirable.

The method of introducing impurity according to the invention is characterized in that the first step includes a step of irradiating the plasma including krypton (Kr).

According to the above method, it is expected from the experimental result that it is possible to form the amorphous layer to a depth smaller than 2.5 nm. Therefore, it is possible to efficiently form the impurity region to a desired depth.

The method of introducing impurity according to the invention is characterized in that the first step includes a step of irradiating the plasma including xenon (Xe).

According to the above method, it is expected from the experimental result that it is possible to form the amorphous layer to a depth smaller than 2.1 nm. Therefore, it is possible to form the impurity region in a shallow profile.

The method of introducing impurity according to the invention is characterized in that the first step includes a step of irradiating the plasma including radon (Rn).

According to the above method, it is expected from the experimental result that it is possible to form the amorphous layer to a depth smaller than 1.2 nm. Therefore, it is possible to efficiently form the impurity region to a desired depth.

The method of introducing impurity according to the invention is characterized in that the first step includes a step of forming an amorphous layer to a depth X represented by the following formula:

1(1/0.481)·In(Y/121.37)<X<(Y/270.87)^{-(1.2604)},

where Y (in unit of ‘u’) stands for an atomic weight of elements constituting the amorphous layer and X (in unit of ‘nm’) stands for the depth of the amorphous layer.

It has been found from the experimental result that the relation between the atomic weight of element used in plasma and the depth of the amorphous layer to be formed can be represented by the above formula. Therefore, by selecting the type of element used in the plasma on the basis of a desired depth of the amorphous layer, it is possible to easily obtain the desired depth. In this case, the plasma may be directly irradiated, or ions extracted from the plasma are irradiated using an ion shower method.

The method of introducing impurity according to the invention is characterized in that the second step includes a step of forming the impurity introducing layer by irradiating the plasma including B₂H₆ gas having a concentration range of between 0.001% and 1.0%.

According to the above method, it is possible to form a semiconductor layer having good optical absorption ratio with respect to light having wavelength of 400 nm or more. Moreover, it is possible to realize a dose amount of the impurity which is generally used in the semiconductor. Accordingly, it is possible to form the impurity region having a practical resistance value where the impurity is well activated.

The method of introducing impurity according to the invention is characterized in that the step of forming the impurity introducing layer includes a step of forming the impurity introducing layer by irradiating He plasma containing B₂H₆ gas having a concentration range of between 0.001% and 1.0%.

According to the above method, in addition to the above-mentioned advantages, since helium element is easily diffused toward the outside of the semiconductor substrate in the annealing process and does not remain in the semiconductor substrate after the annealing, it is easy to recover crystallinity of silicon. Moreover, since the atomic radius of helium element is smaller than that of silicon or germanium, it rarely hinders the recovery of crystals even when a little amount of helium element remains in the silicon. Moreover, since helium is an inactive element, it is unlikely to react with silicon within the semiconductor substrate even in the process of plasma irradiation. Further, it is possible to introduce the impurity by the dose amount that is generally used in ion implantation.

The method of introducing impurity according to the invention is characterized in that the first step includes a step of irradiating the plasma including hydrogen.

According to the above method, since hydrogen is easily diffused toward the outside of the semiconductor substrate in the annealing process and does not remain in the semiconductor substrate after the annealing, it is easy to recover crystallinity of silicon and it is thus desirable. Moreover, since the atomic radius of hydrogen element is smaller than that of silicon or germanium, it rarely hinders the recovery of crystals even when a little amount of hydrogen element remains in the silicon and it is thus desirable.

An impurity introducing apparatus according to the invention is characterized in that the apparatus includes an irradiating unit irradiating plasma composed of particles which are electrically inactive in a semiconductor layer to a surface of a solid base body and introducing unit introducing the impurity to the surface of the solid base body.

According to the above apparatus, it is possible to efficiently realize the above-mentioned method.

The impurity introducing apparatus according to the invention is characterized in that the apparatus further includes an annealing unit for activating the introduced impurity.

The impurity introducing apparatus according to the invention is characterized in that the introducing unit, the irradiating unit and the annealing unit are configured to be executed in the same chamber in a sequential manner.

According to the above apparatus, since it is possible to downsize the apparatus, it is possible to perform a series of processes while preventing the solid base body as the object to be processed from being in contact with external air.

The impurity introducing apparatus according to the invention is characterized in that at least two units of the introducing unit, the irradiating unit and the annealing unit are configured to be executed simultaneously in the same chamber.

According to the above apparatus, it is possible to downsize the apparatus.

### ADVANTAGE OF THE INVENTION

According to the impurity introducing method of the invention, since impurity is introduced to the amorphous layer formed by irradiating plasma composed of inactive gas, the impurity is efficiently introduced, thereby making it possible to form a shallow junction with high-precision. Moreover, since it is possible to form fine pores in the amorphous layer and efficiently introduce the impurity in the pores, it is possible to form a fine impurity region and thus it is possible to form the junction in the fine impurity region with high-precision.

### BRIEF DESCRIPTION OF THE DRAWINGS

FIG. 1 is a sectional diagram showing an essential part of an apparatus used in an exemplary embodiment of the invention.

FIG. 2 is a diagram showing an AFM surface morphology of a silicon substrate after a plasma treatment related to the invention.

FIG. 3 is a diagram showing an AFM surface morphology of a silicon substrate after a plasma treatment according to a comparative example.

FIG. 4 is a diagram showing an AFM surface morphology of a silicon substrate after an ion implantation according to the comparative example.

FIG. 5 is a diagram showing the relation between the thickness of an amorphous layer, a surface roughness and a bias voltage with respect to an exemplary embodiment and the comparative example.

FIG. 6 is a diagram showing a sectional TEM image according to an example of the invention.

FIG. 7 is a diagram showing another sectional TEM image according to the example of the invention.

FIG. 8 is a diagram showing a sectional TEM image according to the comparative example.

FIG. 9 is a diagram showing a further sectional TEM image according to the example of the invention.

FIG. 10 is a diagram showing SINS profiles of boron after introducing impurity with respect to an exemplary embodiment of the invention and the comparative example.

FIG. 11 is a diagram showing the relation between a sheet resistance and a bias voltage when performing an RTA with respect to an exemplary embodiment of the invention and the comparative example.

FIG. 12 is a diagram showing the relation between a sheet resistance and a bias voltage when performing a spike RTA with respect to an exemplary embodiment of the invention and the comparative example.

FIG. 13 is a diagram showing the relation between the depth of an amorphous layer related to the invention and the atomic weight of atoms used in a plasma irradiation.

FIG. 14 is a diagram showing the relation between the thickness of an amorphous layer and a bias voltage in the case of amorphism by irradiating plasma of helium gas, mixed gas of argon and helium, and nitrogen gas.

FIG. 15 is a diagram showing the relation between a mixture ratio of argon gas and the thickness of an amorphous layer in the case of amorphism by irradiating mixed gas plasma of argon and helium.

FIG. 16 is a diagram showing the relation of a bias voltage and a sheet resistance in the case where amorphism by irradiating helium and amorphism by irradiating mixed gas plasma of argon and helium are performed as a pre-process of plasma-doping of B₂H₆ diluted with helium and an RTA.

FIG. 17 is a diagram for comparing the optical absorption coefficients with respect to light of 530 nm wavelength in accordance with the invention and the comparative example.

FIG. 18 is a diagram for comparing the thickness of an amorphous layer when the mixture ratio of B₂H₆ gas and helium gas is interchanged with respect to the invention and the comparative example.

FIG. 19 is a diagram for explaining variation of a boron dose amount when the mixture ratio of B₂H₆ gas and helium gas is interchanged.

FIG. 20 is a sectional diagram showing an essential part of an ion shower apparatus used in an exemplary embodiment of the invention.

### REFERENCE NUMERALS

1 HIGH FREQUENCY POWER SOURCE
2 MATCHING BOX
3 COIL
4 MASSFLOW CONTROLLER
5 MASSFLOW CONTROLLER
6 TURBO MOLECULAR PUMP
7 CONDUCTANCE VALVE
8 DRY PUMP
9 CIRCULATOR
10 DC POWER SUPPLY
11 MATCHING BOX
12 HIGH FREQUENCY POWER SOURCE
13 SUBSTRATE TO BE PROCESSED
14 LOWER ELECTRODE
15 VACUUM CHAMBER

### BEST MODE FOR CARRYING OUT THE INVENTION

Hereinafter, exemplary embodiments of the invention will be described in detail with reference to the accompanying drawings. However, the invention is not limited to the following exemplary embodiments.

### Exemplary Embodiment 1

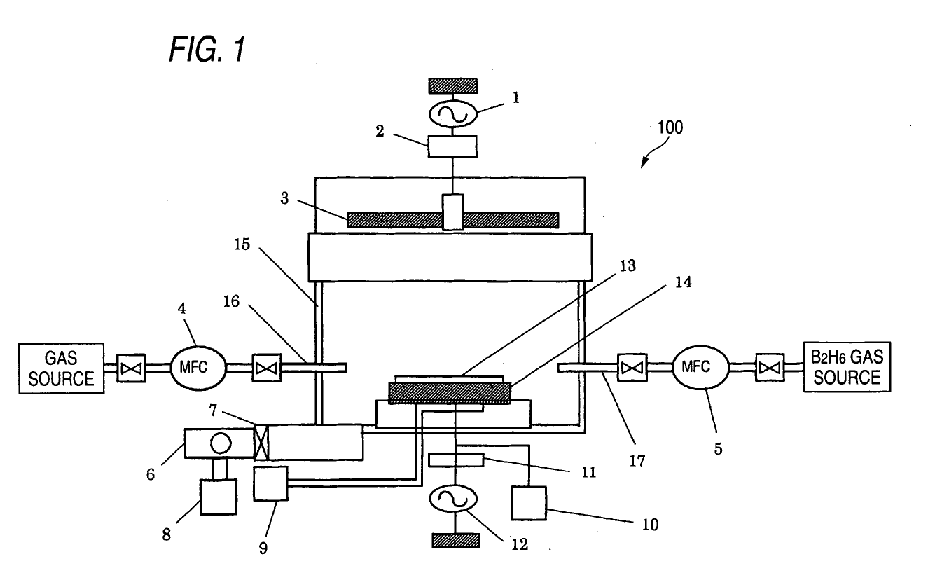

FIG. 1 is a sectional diagram showing an essential part of an impurity introducing apparatus in accordance with an exemplary embodiment of the invention.

As shown in FIG. 1, the impurity introducing apparatus 100 is configured to perform plasma doping, plasma irradiation and annealing in the apparatus in a sequential manner. Specifically, in the apparatus 100, a semiconductor substrate serving as a substrate to be processed 13 is provided on a susceptor serving as an lower electrode 14 disposed in a vacuum chamber 15, and a plasma generating area is formed in the vicinity of the surface of the substrate, whereby the plasma doping and the plasma irradiation are performed. A coil 3 is fixed to a high frequency power source through a matching box 2, whereby a high frequency power is supplied between the coil 3 and the lower electrode 14. The lower electrode 14 is connected not only to a DC power supply 10 but also to the high frequency power source 12 through the matching box 11.

The degree of vacuum in the vacuum chamber 15 is controlled by a dry pump 8 and a turbo molecular pump 6 connected through a conductance valve 7. The lower electrode 14 is configured to be circulated by a circulator 9. The chamber 15 includes a mass-flow controller 4 for inactive gas which introduces thereto inactive gas such as helium gas and a mass-flow controller 5 for impurity gas which is disposed at an opposite portion in the chamber 15 and introduces thereto diborane gas.

The base body of the impurity introducing apparatus 100 is constructed as described above. It is important that the apparatus 100 is of a sheet feed type and the entire volume, particularly, the volume of the vacuum chamber 15 is made as small as possible to enable a rapid treatment. It is desirable that the plasma generating area is formed from helicon wave plasma source, ECR (Electron Cyclotron Resonance) plasma source, ICP plasma source or the like. With these plasma sources, impurities to be introduced to the silicon substrate 13 to be processed or materials containing gas for plasma irradiation, i.e., B₂H₆ and helium gas in this case, is excited into plasma state through an individual process.

In a supply system for gaseous material containing the impurities, a predetermined amount of gaseous material is supplied to the vacuum chamber 15 through the mass-flow controllers 4 and 5. The flow rate of the gas is configured to be individually controlled by the mass-flow controllers 4 and 5. The amount of supply is determined by the volume, temperature and vacuum degree of the mass-flow controller 4 and 5 and the vacuum chamber 15 and monitored respectively through a thermometer and a pressure gauge, whereby the temperature and pressure is stably controlled by a respective temperature controller and a respective pressure controller.

In the apparatus 100, the silicon substrate 13 is conveyed into process chamber 15 and disposed on the lower electrode 14. An introducing pipe 16 for rare gas and an introducing pipe 17 for diborane gas are individually coupled with the vacuum chamber 15. Rare gas is used for making the surface of the silicon substrate to be amorphous by irradiating rare gas plasma to the surface. Diborane gas is made amorphous to be used for plasma-doping or introduced into the vacuum chamber 15 in a gaseous state to be used for gas-doping.

First, after setting the vacuum degree in the vacuum chamber 15 a desired degree, the introducing pipe 16 for rare gas is opened to generate plasma of rare gas and plasma composed only of electrically inactive particles is irradiated to the silicon substrate 13, thereby forming an amorphous layer. The amorphous layer may or may not have fine pores depending on conditions for the plasma irradiation.

Then, the introducing pipe 17 for diborane gas is opened to form an impurity introducing layer in a predetermined area of the silicon substrate 13 which has been made amorphous.

Thereafter, a shallow junction is formed through an annealing device (not shown).

In this way, a shallow, low-resistance and high-precision impurity doping is realized.

### Exemplary Embodiment 2

Hereinafter, a second exemplary embodiment of the invention will be described.

Although the impurity was introduced after making the surface of the silicon substrate to be amorphous in the first exemplary embodiment, the second exemplary embodiment is characterized in that an amorphous layer is formed by irradiating inactive gaseous plasma after introducing the impurity.

In other words, after setting the vacuum degree in the vacuum chamber 15, the introducing pipe 17 for diborane gas is opened to form an impurity introducing layer in a predetermined area of the silicon substrate 13.

Then, the introducing pipe 16 for rare gas is opened to generate the plasma of rare gas, and plasma composed only of electrically inactive particles is irradiated to the silicon substrate 13, thereby forming an amorphous layer. The amorphous layer may or may not have fine pores depending on conditions for the plasma irradiation.

Thereafter, a shallow junction is formed through an annealing device (not shown).

In this way, a shallow, low-resistance and high-precision impurity doping is realized.

### Exemplary Embodiment 3

Hereinafter, a third exemplary embodiment of the invention will be described.

Although the impurity was introduced after making the surface of the silicon substrate to be amorphous in the first exemplary embodiment, the third exemplary embodiment is characterized in that a step of introducing the impurity is performed simultaneously with a step of irradiating inactive gaseous plasma to form an amorphous layer.

In other words, after setting the vacuum degree in the vacuum chamber 15, the introducing pipe 16 for rare gas and the introducing pipe 17 for diborane gas are opened together to generate plasma of rare gas and plasma composed only of electrically inactive particles is irradiated to the silicon substrate 13, thereby forming an amorphous layer, while forming an impurity introducing layer in a predetermined area of the silicon substrate 13. The amorphous layer may or may not have fine pores depending on conditions for the plasma irradiation.

Thereafter, a shallow junction is formed through an annealing device (not shown).

In this way, a shallow, low-resistance and high-precision impurity doping is realized.

Next, examples of the invention will be described in detail.

In the following examples, a process for a surface amorphism of a solid base body itself will be described.

### EXAMPLE 1

### Surface Roughness

First, description will be made to a surface roughness in a process for forming an amorphous layer by plasma irradiation.

In the vacuum chamber 15, plasma was irradiated to the silicon substrate as the object 13 to be processed.

In this example, a helicon wave plasma source was used as a plasma source.

Moreover, helium gas was used.

First, helium plasma was irradiated to the silicon substrate 13. The plasma irradiation was performed in a condition of 0.9 Pa of pressure, 7 seconds of plasma irradiation time and 75 V to 310 V of a bias voltage. After stopping the plasma irradiation and evacuating the vacuum chamber 15 for the first time, the vacuum chamber 15 was purged with nitrogen gas and the substrate was removed from the vacuum chamber 15. An AFM surface morphology of the removed silicon substrate 13 was observed.

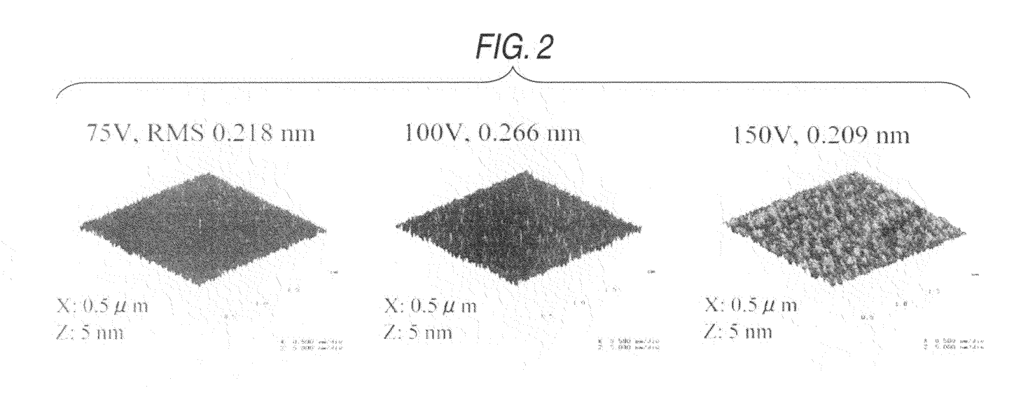

FIG. 2 shows a result of the AFM surface observation when the bias voltage of helium plasma irradiation was changed in the range of between 75 V and 150 V, in accordance with an example of the invention. The surface roughness of the silicon substrate 21 was observed to be 0.3 nm in RMS.

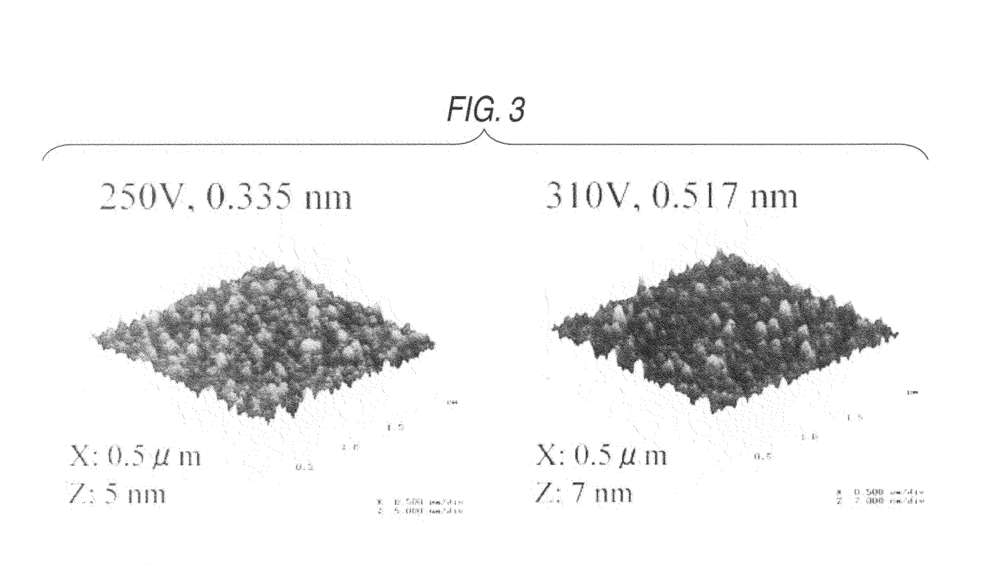

FIG. 3 shows a result of the AFM surface observation when the helium plasma irradiation was performed at bias voltages of 250 V and 310 V, respectively, in accordance with a comparative example. The surface roughness of the silicon substrate 21 was observed to be 0.355 nm and 0.517 nm in RMS, respectively, and the surface was found to be roughened.

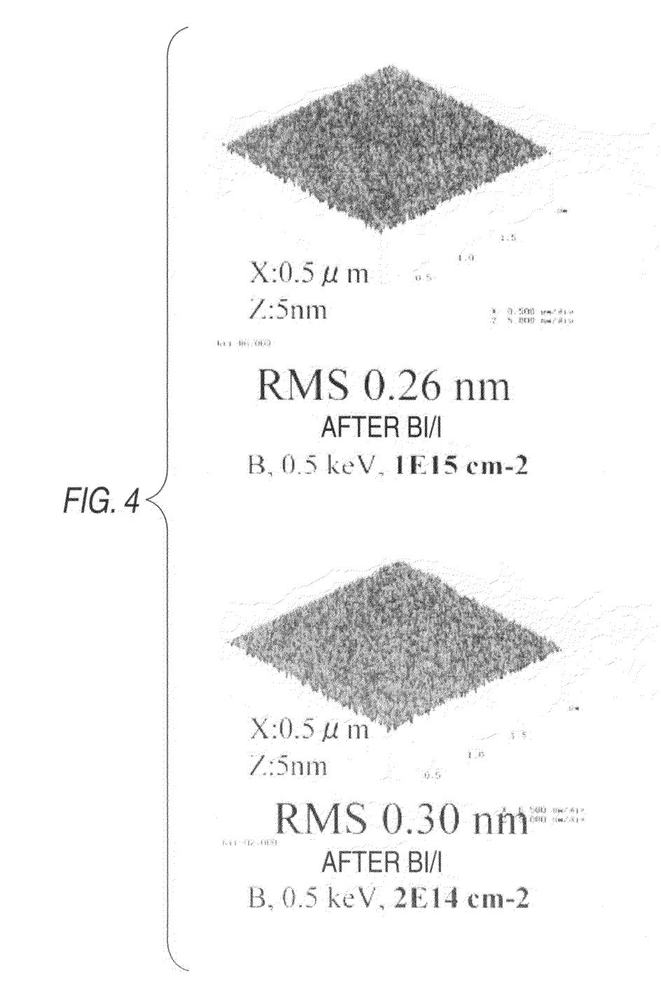

FIG. 4 shows the surface of the silicon substrate after boron is ion-implanted to the silicon substrate 21 using a custom condition, in accordance with another comparative example. Acceleration energy of 0.5 kV and the dose amount of boron of 1×10¹⁵ cm⁻² and 2×10¹⁴ cm⁻² were used. The surface roughness of the silicon substrate 13 was observed to be smaller than 0.3 nm. Since the ion implantation has been widely used in the industry, the surface roughness of 0.3 nm in RMS is considered to be allowable in manufacturing processes.

From the above results, when the application voltage used in the plasma irradiation during the process of forming an amorphous layer by irradiating plasma is lower than 250 V, the surface roughness is smaller than that of the ion implantation, which does not seem to cause any problem in practical use. Therefore, it can be seen that a bias voltage lower than 250 V is desirable.

### EXAMPLE 2

### Thickness of Amorphous Layer

Next, description will be made to the thickness of an amorphous layer during the process of forming the amorphous layer by irradiating plasma.

In the vacuum chamber 15, plasma was irradiated to the silicon substrate as the object 13 to be processed.

In this example, a helicon wave plasma source was used as a plasma source. Moreover, helium gas was used.

First, helium plasma was irradiated to the silicon substrate 13. The plasma irradiation was performed in a condition of 0.9 Pa of pressure, 7 seconds of plasma irradiation time and 75 V to 310 V of a bias voltage. After stopping the plasma irradiation and evacuating the vacuum chamber 15 for the first time, the vacuum chamber 15 was purged with nitrogen gas and the substrate was removed from the vacuum chamber 15. The thickness of the amorphous layer on the surface of the removed silicon substrate 13 was measured with an ellipsometry. Moreover, the thickness of the amorphous layer for certain samples was observed from the sectional TEM images thereof so as to compare them with the ellipsometry measurement result. Then, the ellipsometry measurement result was corrected on the basis of the sectional TEM measurement result so as to determine the depth of the amorphous layer for all samples.

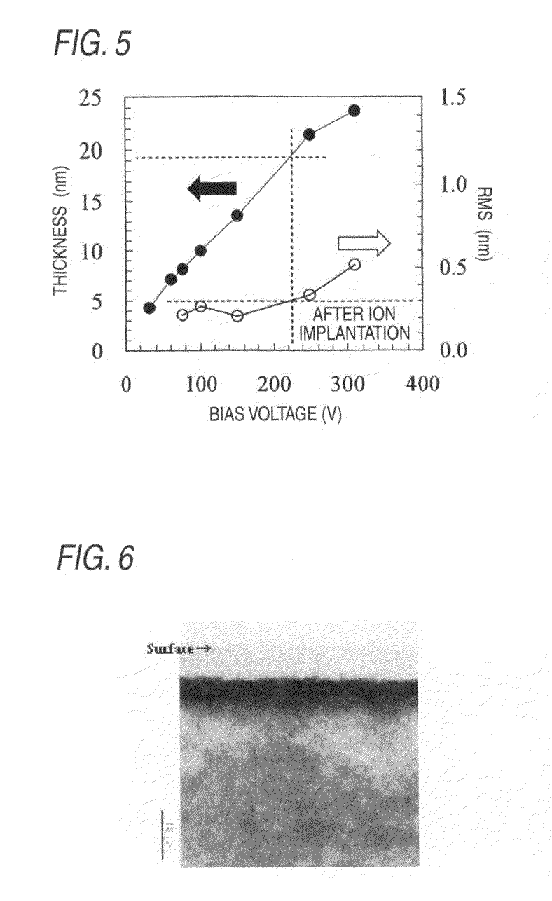

FIG. 5 shows the relation between a bias voltage and the thickness of the amorphous layer. In FIG. 5, the relation between the bias voltage and the surface roughness described above is also shown for reference. The thickness of the amorphous layer increased with the increase of the bias voltage. The thickness range of the amorphous layer that can be formed was between 4.5 nm and 24 nm. In view of the surface roughness, bias voltages lower than 225 V may not cause any problem in practical use. The thickness of the amorphous layer corresponding to the bias voltage range is smaller than 19 nm. In other words, the thickness of the amorphous layer smaller than 19 nm does not cause any problem in practical use in view of the surface roughness.

### EXAMPLE 3

### Porous Silicon

Next, description will be made to formation of pores in the amorphous layer during the process of forming the amorphous layer by irradiating plasma. The pores refer to portions having lower density in the silicon substrate and are referred to as microcapsules or bubbles.

In the vacuum chamber 15, plasma was irradiated to the silicon substrate as the object 13 to be processed.

In this example, a helicon wave plasma source was used as a plasma source.

Moreover, helium gas was used.

First, helium plasma was irradiated to the silicon substrate 13. The plasma irradiation was performed in a condition of 1500 W of a source power, 0.9 Pa of pressure, 7 seconds of plasma irradiation time and 75 V, 150 V, 200 V and 310 V of a bias voltage. After stopping the plasma irradiation and evacuating the vacuum chamber 15 for the first time, the vacuum chamber 15 was purged with nitrogen gas and the substrate was removed from the vacuum chamber 15. A sectional TEM image of the removed silicon substrate 13 was observed.

FIG. 6 shows a sectional TEM image of the silicon substrate 13 when a bias voltage of 75 V was used. The amorphous layer was formed to a depth of 8 nm from the surface. Pores were not observed. There is also a possibility that fine pores were too small to be observed by the TEM image. In this way, the amorphous layer having good optical absorption characteristics was formed.

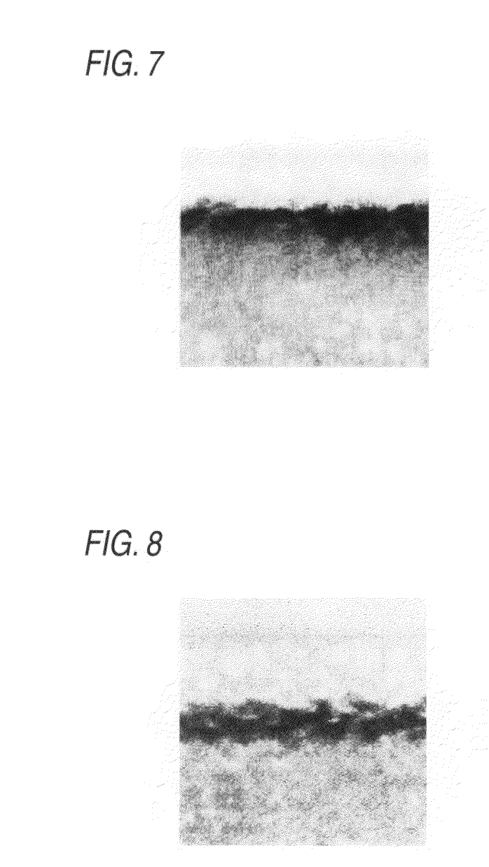

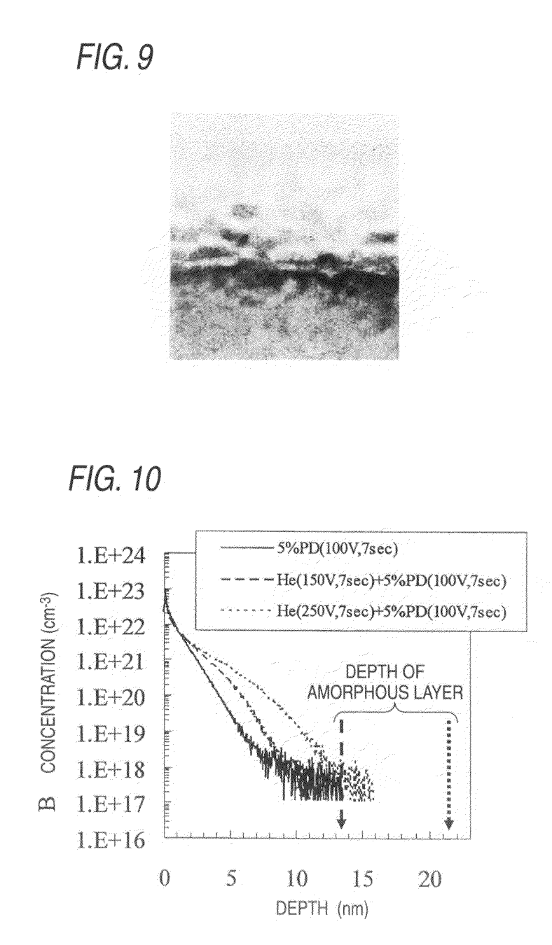

FIG. 7 shows a sectional TEM image of the silicon substrate 13 when a bias voltage of 150 V was used. The amorphous layer was formed to a depth of 13.5 nm from the surface. Pores (micro pores) having diameter smaller than 6.4 nm were observed at a depth range of between 3.2 nm and 9.6 nm from the surface. Pores refer to portions having densities lower than those of other portions of the amorphous silicon layer due to the presence of the micro pores.

The thickness of the amorphous silicon layer was 13.5 nm at that moment. Since the pores are formed in the amorphous silicon layer, it is possible to form a fine impurity region with a steep impurity concentration profile and good crystallization characteristics by selectively introducing the impurity to the porous region.

FIG. 8 shows a sectional TEM image of the silicon substrate 13 when a bias voltage of 200 V was used. The amorphous layer was formed to a depth of 17.5 nm from the surface. Pores having diameter smaller than 9.5 nm were observed at a depth range of between 3.2 nm and 14.5 nm from the surface. It can be seen from the sectional TEM image that the pores showed clearer outlines compared with the case where a bias voltage of 150 V was used. This may be resulted from the fact that the densities of the pores have been decreased to a value smaller than that of a crystalline silicon layer.

The thickness of the amorphous silicon layer was 17.5 nm at that moment. Since the pores are formed in the amorphous silicon layer, it is possible to form a fine impurity region with a steep impurity concentration profile and good crystallization characteristics by selectively introducing the impurity to the porous region.

FIG. 8 shows a sectional TEM image of the silicon substrate 13 when a bias voltage of 310 V was used. The amorphous layer was formed to a depth of 24 nm from the surface. Pores having diameter smaller than 9.5 nm were observed at a depth range of between 3.2 nm and 19 nm from the surface. It can be seen from the sectional TEM image that the pores showed clearer outlines compared with the case where a bias voltage of 200 V was used. This may be resulted from the fact that the densities of the pores have been decreased to a value smaller than that of a crystalline silicon layer, compared with the case where a bias voltage of 200 V was used. Moreover, a damage layer was formed at an interface between the amorphous layer and the crystalline silicon layer.

The thickness of the amorphous silicon layer was 24 nm at that moment. Since the pores are formed in the amorphous silicon layer, it is possible to form a fine impurity region with a steep impurity concentration profile and good crystallization characteristics by selectively introducing the impurity to the porous region.

In this way, it is possible to control the thickness of the amorphous layer, locations, diameters and densities of the pores by changing the bias voltage during the process of irradiating helium plasma.

### EXAMPLE 4

### Comparison of As-Doped SIMS Profiles

Next, description will be made to the effect of the amorphous layer having pores therein on a depth-wise impurity profile.

In the vacuum chamber 15, plasma was irradiated to the silicon substrate as the object 13 to be processed.

In this example, a helicon wave plasma source was used as a plasma source.

Moreover, helium gas was used in an amorphism process, and diborane gas was used in a doping process.

First, helium plasma was irradiated to the silicon substrate 13. The plasma irradiation was performed in a condition of 1500 W of a source power, 0.9 Pa of pressure, 7 seconds of plasma irradiation time and 150 V and 250 V of bias voltages. After stopping the plasma irradiation and evacuating the vacuum chamber 15, mixed gas plasma of diborane and helium was irradiated without removing the silicon substrate 13 from the vacuum chamber 15. The mixed gas of diborane gas of 5% and helium gas of 95% in concentration ratio was used. The plasma irradiation was performed in a condition of 1000 W of a source power, 2.5 Pa of pressure, 7 seconds of plasma irradiation time and 100 V of a bias voltage. After stopping the plasma irradiation and evacuating the vacuum chamber 15, the vacuum chamber 15 was purged with nitrogen gas and the substrate was removed from the vacuum chamber 15.

In addition, samples which were not subjected to the helium plasma irradiation were prepared for comparison. In other words, mixed gas plasma of diborane and helium was irradiated to the silicon substrate 13 for the first time. The mixed gas of diborane gas of 5% and helium gas of 95% in concentration ratio was used. The plasma irradiation was performed in a condition of 1000 W of a source power, 2.5 Pa of pressure, 7 seconds of plasma irradiation time and 100 V of a bias voltage. After stopping the plasma irradiation and evacuating the vacuum chamber 15 for the first time, the vacuum chamber 15 was purged with nitrogen gas and the substrate was removed from the vacuum chamber 15.

Then, SIMS profiles of boron concentration in a depth direction of the removed silicon substrate 13 were measured with respect to the entire samples.

FIG. 10 shows As-doped SIMS profiles. The profile shown with a solid line shows an As-doped SIMS profile corresponding to the case where the plasma doping was performed using a mixed gas of B₂H₆ gas of 5% and helium gas of 95% without helium plasma irradiation in a condition of 1000 W of a source power, 0.9 Pa of pressure, 7 seconds of plasma irradiation time and 100 V of a bias voltage. The profile shown with a dashed line shows an As-doped SIMS profile corresponding to the case where the plasma doping was performed in the same condition as that described above after irradiating helium plasma at 150 V of a bias voltage. The profile shown with a dotted line shows an As-doped SIMS profile corresponding to the case where the plasma doping was performed in the same condition as that described above after irradiating helium plasma at 250 V of a bias voltage.

The result obtained from the SIMS profiles of boron concentration in a depth direction showed that the profiles varied depending on the bias voltage of helium plasma irradiation even in the same the plasma doping condition. Moreover, when helium plasma was irradiated, boron was deeply doped compared with the case where the helium plasma was not irradiated. When boron was doped to a depth corresponding to the boron concentration of 5E18 cm⁻³, the doping depth corresponded to 50% to 60% of the depth of the amorphous layer formed by the helium plasma irradiation.

In addition, the doping depth increased as the depth of the amorphous layer formed by the helium plasma irradiation increased. In other words, the doping depth of boron was 8.1 nm when an amorphous layer of 13.5 nm thickness was formed by irradiating the helium plasma, while the doping depth of boron was 11.2 nm when an amorphous layer of 21.4 nm thickness was formed by irradiating the helium plasma. This result is contrary to the result obtained from the combined use of Ge pre-amorphism ion-implantation using ion implantation and boron ion-implantation. In the case of ion-implantation, by performing pre-amorphism using Ge pre-amorphism ion-implantation, it advantageously prevents channeling effect.

In other words, in the Ge pre-amorphism ion-implantation, it is reported that the pre-amorphism shallows the doping depth. Therefore, the experimental result of the invention demonstrates a possibility that when fine micro capsules are produced in Si substrate through helium plasma irradiation, boron is selectively introduced into pores by stuffing the boron into the inside of the pores.

The result is summarized on the basis of the steepness of the profiles. The steepness is represented by a distance in a depth direction when the boron concentration changes from 1E19 cm⁻³ to 1E18 cm⁻³. As the distance decreases, a steeper profile is realized. A deeper profile is desirable in that the impurity concentration is abruptly changed in the vicinity of junction boundaries between p-region and n-region of the p-n junction. The steepness of the samples which was not subjected to the helium plasma irradiation was measured to be 3.2 nm/dec. To the contrary, the steepness of the samples which was subjected to plasma doping after irradiating the helium plasmas at a bias voltage of 150 V was measured to be 1.7 nm/dec. Moreover, the steepness of the samples which was subjected to plasma doping after irradiating the helium plasmas at a bias voltage of 250 V was measured to be 2.5 nm/dec. Since the steepness of the profiles increases in the case of performing the helium plasma irradiation, the advantage of the invention is approved.

### EXAMPLE 5

### Effect of Bias Voltage of Helium Plasma Irradiation on Sheet Resistance

Next, description will be made to the relation between the bias voltage of the helium plasma irradiation and a sheet resistance. In the vacuum chamber 15, plasma was irradiated to the silicon substrate as the object 13 to be processed. In this example, a helicon wave plasma source was used as a plasma source.

Moreover, helium gas was used.

First, helium plasma was irradiated to the silicon substrate 13. The plasma irradiation was performed in a condition of 0.9 Pa of pressure, 7 seconds of plasma irradiation time and 75 V, 150 V, 200 V and 250 V of bias voltages. After stopping the plasma irradiation, the vacuum chamber 15 was evacuated for 5 seconds. Then, plasma of B₂H₆ gas diluted with helium gas was irradiated.

The plasma irradiation was performed in a condition of 2.5 Pa of pressure, 7 seconds of plasma irradiation time and 100 V of a bias voltage. After stopping the plasma irradiation and evacuating the vacuum chamber 15, the vacuum chamber 15 was purged with nitrogen gas and the substrate was removed from the vacuum chamber 15.

In addition, samples which were not subjected to the helium plasma irradiation were prepared for comparison. In other words, the plasma mixed gas plasma of diborane and helium was irradiated to the silicon substrate 13 for the first time. The plasma irradiation was performed in a condition of 2.5 Pa of pressure, 7 seconds of plasma irradiation time and 100 V of a bias voltage. After stopping the plasma irradiation and evacuating the vacuum chamber 15, the vacuum chamber 15 was purged with nitrogen gas and the substrate was removed from the vacuum chamber 15.

Thereafter, the entire samples were subjected to a heat treatment at 900° C. by using a rapid thermal annealing (RTA) with a temperature increasing rate of 12° C./sec and a temperature decreasing rate of 6° C./sec. The temperature was maintained at 900° C. for zero (0) second. After the heat treatment, the sheet resistance was measured using a four probe method.

The dose amount of boron was about 2×10¹⁵ cm⁻² and substantially the same dose amount was applied to the entire samples.

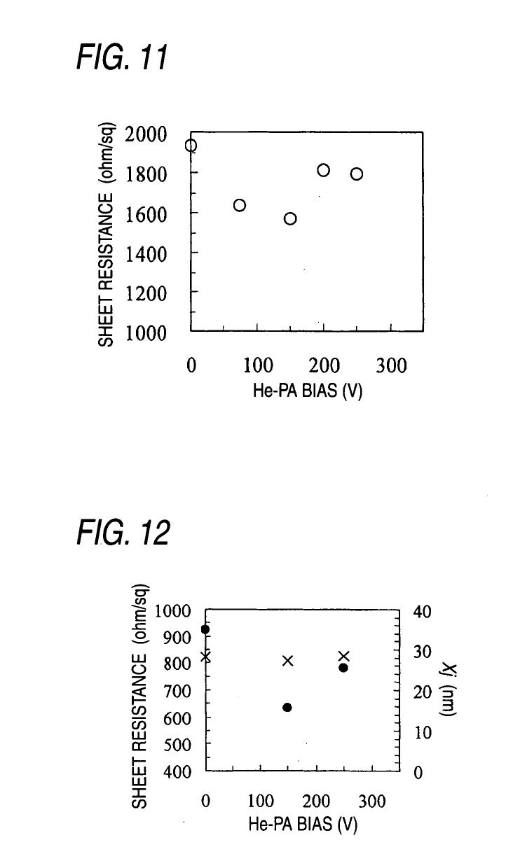

FIG. 11 shows the relation between the bias voltage of the helium plasma irradiation and the sheet resistance. When the helium plasma irradiation was not performed, i.e., when the plasma irradiation was performed using only the B₂H₆ gas diluted with helium gas, the sheet resistance was measured to be 1934 ohm/sq. The sheet resistance was decreased to 1570 ohm/sq by performing the helium plasma irradiation at a bias voltage of 150 V as a pre-process. The decreased amount of the sheet resistance was 19%. However, the sheet resistance abruptly increased when the bias voltage of the helium plasma irradiation exceeds a point where the sheet resistance becomes the smallest. In other words, when the bias voltage of the helium plasma irradiation was increased to 200 V, the sheet resistance was 1815 ohm/sq, which is higher than the case of the bias voltage of 150 V.

### EXAMPLE 6

### Effect of Bias Voltage of Helium Plasma Irradiation on Junction Depth

Next, description will be made to the relation between the bias voltage of the helium plasma irradiation and a sheet resistance.

In the vacuum chamber 15, plasma was irradiated to the silicon substrate as the object 13 to be processed.

In this example, a helicon wave plasma source was used as a plasma source.

Moreover, helium gas was used.

First, helium plasma was irradiated to the silicon substrate 13. The plasma irradiation was performed in a condition of 0.9 Pa of pressure, 7 seconds of plasma irradiation time and 75 V, 150 V and 250 V of bias voltages. After stopping the plasma irradiation, the vacuum chamber 15 was evacuated for 5 seconds. Then, plasma of B2H2 gas diluted with helium gas was irradiated. The plasma irradiation was performed in a condition of 2.5 Pa of pressure, 7 seconds of plasma irradiation time and 200 V of a bias voltage. After stopping the plasma irradiation and evacuating the vacuum chamber 15, the vacuum chamber 15 was purged with nitrogen gas and the substrate was removed from the vacuum chamber 15.

In addition, samples which were not subjected to the helium plasma irradiation were prepared for comparison. In other words, the plasma mixed gas plasma of diborane and helium was irradiated to the silicon substrate 13 for the first time.

The plasma irradiation was performed in a condition of 2.5 Pa of pressure, 7 seconds of plasma irradiation time and 200 V of a bias voltage. After stopping the plasma irradiation and evacuating the vacuum chamber 15, the vacuum chamber 15 was purged with nitrogen gas and the substrate was removed from the vacuum chamber 15.

Thereafter, the entire samples were subjected to a heat treatment at 1000° C. by using a spike rapid thermal annealing (spike PTA) with a temperature increasing rate of 200° C./sec and a temperature decreasing rate of 52° C./sec. The temperature was maintained at 1000° C. for zero (0) second. After the heat treatment, the sheet resistance was measured using a four probe method. Moreover, SIMS profiles after the heat treatment were measured with respect to the entire samples.

The dose amount of boron was about 2×10¹⁵ cm⁻² and substantially the same dose amount was applied to the entire samples.

From the above result, by irradiating inactive plasma at a bias voltage smaller than 150 V as a pre-process of the impurity introduction so as to form an amorphous layer to a depth range of between 4.5 nm and 19 nm, it is possible to form a low-resistance impurity region with low irregularity.

In addition, the relation between the bias voltage of the helium plasma irradiation and a junction depth Xj was measured.

FIG. 12 shows the measurement result of the relation between the bias voltage of the helium plasma irradiation and a junction depth Xj. In FIG. 12, the sheet resistance is also shown. The sheet resistance was the lowest when the helium plasma irradiation was performed at a bias voltage of 150 V as a pre-process. To the contrary, the junction depths for the entire samples were substantially the same when the boron concentration was 1E18 cm⁻².

In this way, there is an optimal bias voltage of the helium plasma irradiation, where the sheet resistance becomes the lowest without changing the junction depth even in the same dose amount of boron.

### EXAMPLE 7

### Effect of Type of Gas Used in Plasma Irradiation on Depth of Amorphous Layer

Next, description will be made to the relation between atomic weight of elements of plasma and the depth of an amorphous layer that can be formed at the time of making silicon crystals to be amorphous by irradiating the plasma.

In the vacuum chamber 15, plasma was irradiated to the silicon substrate as the object 13 to be processed.

In this example, a helicon wave plasma source and an ICP plasma source were used as a plasma source.

Moreover, helium gas, nitrogen gas, oxygen gas, argon gas and xenon gas were used.

First, plasma using a helicon wave plasma source was irradiated to the silicon substrate 13. Plasma of helium, nitrogen, oxygen, argon and xenon was separately used.

The plasma irradiation was performed in a condition of 0.9 to 2.5 Pa of pressure, 7 to 60 seconds of plasma irradiation time and 75 V to 310 V of a bias voltage. After stopping the plasma irradiation and evacuating the vacuum chamber 15 for the first time, the vacuum chamber 15 was purged with nitrogen gas and the substrate was removed from the vacuum chamber 15.

Similarly, samples were prepared by using the ICP plasma source. A device equipped with the ICP plasma source having a shape or size different from that equipped with the helicon wave plasma source was used. In other words, the experiment was performed by replacing the plasma source and the chamber. First, the plasma was irradiated to the silicon substrate 13. Plasma of helium, nitrogen, oxygen, argon and xenon was separately used. The plasma irradiation was performed in a condition of 1.0 to 3.0 Pa of pressure, 7 to 30 seconds of plasma irradiation time and 490 V to 900 V of a bias voltage. After stopping the plasma irradiation and evacuating the vacuum chamber 15 for the first time, the vacuum chamber 15 was purged with nitrogen gas and the substrate was removed from the vacuum chamber 15.

The depth of the amorphous layer for the entire samples was measured with an ellipsometry.

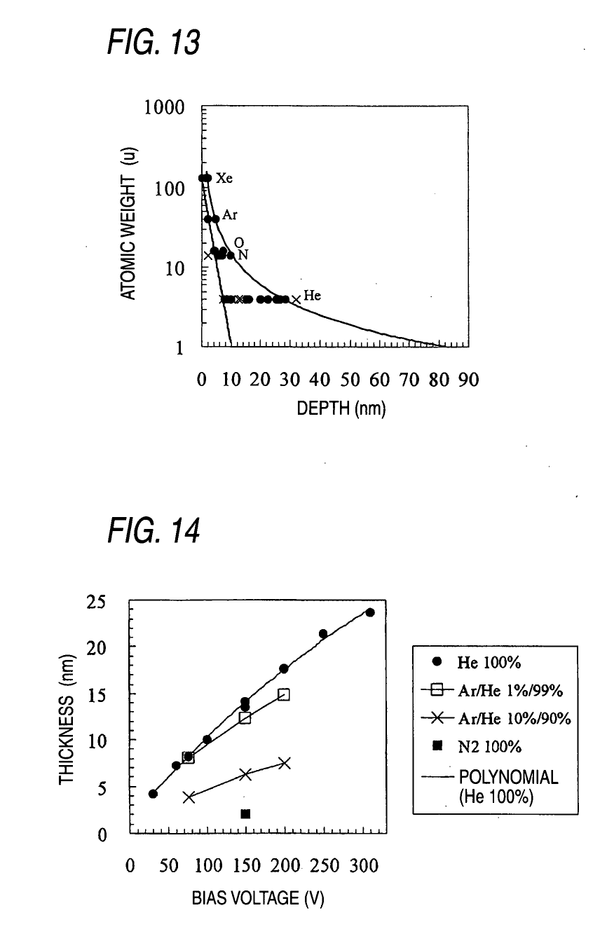

FIG. 13 shows the relation between atomic weight of elements of plasma and the depth of an amorphous layer. In FIG. 13, points denoted by x represent the result corresponding to the vacuum device equipped with the helicon wave plasma source, while points denoted by dark circle represent the result corresponding to the vacuum device equipped with the ICP plasma source. The depth of the amorphous layer decreased as the atomic weight of the used elements increased compared with that of smaller atomic weight, regardless of the type of the vacuum device and the plasma source. Moreover, it can be seen that the depth range of the amorphous layer that can be formed greatly depended on the type of elements.

Specifically, when using helium plasma, it is suitable for forming an amorphous layer to a depth range of between 7 nm and 32 nm, preferably between 7 nm and 27 nm. Moreover, when using nitrogen plasma, it is suitable for forming an amorphous layer to a depth range of between 2 nm and 10 nm, preferably between 4.5 nm and 10 nm. Further, when using oxygen plasma, it is suitable for forming an amorphous layer to a depth range of between 4 nm and 7.2 nm. Furthermore, when using argon plasma, it is suitable for forming an amorphous layer to a depth range of between 2 nm and 4.7 nm. In addition, when using xenon plasma, it is suitable for forming an amorphous layer to a depth smaller than 2.1 nm. When it is desired to form the amorphous layer to a depth range different from the above-mentioned range, the following problem may arise. When it is desired to form the amorphous layer to a depth range shallower than a designated range by using an element, the bias voltage should be lowered to a value lower than a controllable level, thereby making it difficult to control the bias voltage. Meanwhile, when it is desired to form the amorphous layer to a depth range shallower than a designated range by using an element, the high bias voltage should be applied, whereby the size of bias voltage supply is increased or the load applied to the bias voltage supply or an insulating unit of the apparatus becomes great.

Assuming that Y(u) stands for an atomic weight of elements constituting an amorphous layer and X(nm) stands for the depth of the amorphous layer, the depth range of the amorphous layer suitable for the element can be expressed by the range defined by Formulae 1 and 2 in FIG. 13.

Y>121.37exp(−0.481X) [Formula 1]

Y<270.87X^{-1.2684} [Formula 2]

By resolving Formulae 1 and 2 with respect to X, Formula 3 is obtained.

−(1/0.481)·In(Y/121.37)<X<(Y/270.87)^{-(1/1.2684)} [Formula 3]

By selecting the element for the plasma irradiation from Formula 3, it is possible to select the depth of the amorphous layer so as not to increase the size of the apparatus or the load applied to the apparatus.

Conversely, by selecting the depth of the amorphous layer, it is possible to select the element for the plasma irradiation so as not to increase the size of the apparatus or the load applied to the apparatus.

For example, when using hydrogen plasma, it is desirable to form the amorphous layer to a depth range of between 10 nm and 82 nm. Conversely, when it is desired to form the amorphous layer to a depth range of between 10 nm and 82 nm, it is desirable to use hydrogen plasma.

Similarly, when using neon plasma, it is desirable to form the amorphous layer to a depth range of between 3.7 nm and 7.7 nm. Moreover, when using krypton plasma, it is desirable to form the amorphous layer to a depth smaller than 2.5 nm. Further, when using radon plasma, it is desirable to form the amorphous layer to a depth smaller than 1.2 nm.

Furthermore, when using plasma containing silicon, it is desirable to form the amorphous layer to a depth range of between 3 nm and 6 nm. In addition, when using plasma containing germanium, it is desirable to form the amorphous layer to a depth range of between 1.1 nm and 2.8 nm. In addition, when using plasma containing boron, it is desirable to form the amorphous layer to a depth range of between 5 nm and 12.7 nm. In addition, when using plasma containing phosphorous, it is desirable to form the amorphous layer to a depth range of between 2-8 nm and 5.5 nm. In addition, when using plasma containing arsenic, it is desirable to form the amorphous layer to a depth range of between 1 nm and 2.8 nm.

Since these ranges greatly depend on the atomic weight of the elements, it is considered to be effective in the case of being directly exposed to the plasma and being exposed to ion shower.

### EXAMPLE 8

### Amorphism by Plasma Irradiation Using Mixed Gas of Other Types of Rare Gas

In the vacuum chamber 15, plasma was irradiated to the silicon substrate as the object 13 to be processed.

In this example, a helicon wave plasma source was used as a plasma source.

Moreover, a mixed gas of helium and argon was used. In view of mixture ratio, a mixed gas of helium gas of 99% and argon gas of 1% in concentration ratio, a mixed gas of helium gas of 99% and argon gas of 1%, and a mixed gas of helium gas of 90% and argon gas of 10%.

First, helium plasma was irradiated to the silicon substrate 13. The plasma irradiation was performed in a condition of 1500 W of a source power, 0.9 Pa of pressure, 7 seconds of plasma irradiation time and 75 V, 150 V and 200 V of a bias voltage. After stopping the plasma irradiation and evacuating the vacuum chamber 15 for the first time, the vacuum chamber 15 was purged with nitrogen gas and the substrate was removed from the vacuum chamber 15. The depth of the amorphous layer was measured with an ellipsometry.

FIG. 14 shows the relation between the bias voltage of amorphism by irradiating plasma of helium gas, a mixed gas of Ar and He, and N₂ gas and the thickness of the amorphous layer. The thickness of the amorphous layer formed in the bias voltage range of between 75 V and 200 V was in the range of between 8 nm and 18 nm when the amorphism was performed by irradiating helium gas plasma, while the thickness of the amorphous layer was in the range of between 8 nm and 15 nm when the amorphism was performed by irradiating mixed gas plasma of He of 99% and Ar of 1%. When the amorphism was performed by irradiating mixed gas plasma of He of 90% and Ar of 10%, the thickness of the amorphous layer was in the range of between 3.8 nm and 7.5 nm. In this way, by mixing Ar with He, it was possible to change the thickness range of the amorphous layer that can be formed.

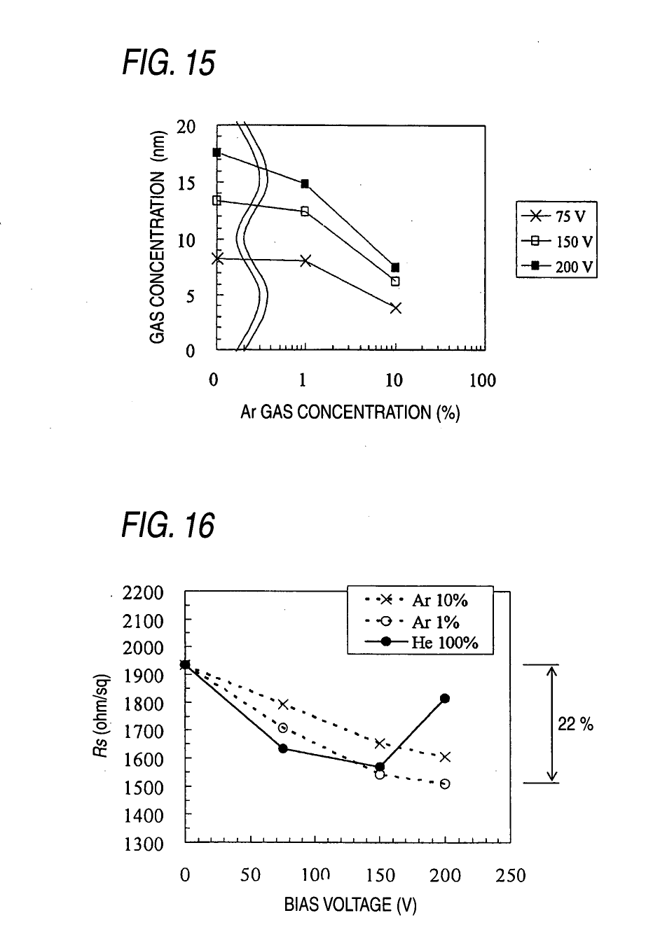

FIG. 15 shows the relation between the mixture ratio of Ar and the thickness of the amorphous layer when the mixture ratio of argon gas and helium gas was changed during the amorphism by plasma irradiation using a mixed gas of Ar and He. The mixture ratio of argon gas to helium gas was 0%/100% (Ar/He), 1%/99% and 10%/90%. The bias voltages of 75 V, 150 V and 200 V and plasma irradiation time of 7 seconds were used. The relation shows that it is possible to change the thickness of the amorphous layer by changing the mixture ratio of argon gas and helium gas. The change in the thickness of the amorphous layer results from the fact that the equivalent atomic weight of elements of plasma is changed by changing the mixture ratio of argon gas and helium gas. Specifically, although the atomic weight of helium is about 4.0 and the atomic weight of argon is about 39.9, it is possible to obtain effect equivalent to the case of using an element having atomic weight lying between 4.0 and 39.9 by mixing both elements. Therefore, it is possible to change the equivalent atomic weight by changing the mixture ratio of argon gas and helium gas.

### EXAMPLE 9

### Effect of Amorphism by Plasma Irradiation Using Mixed Gas of Different Types of Rare Gas on Sheet Resistance

In the vacuum chamber 15, plasma was irradiated to the silicon substrate as the object 13 to be processed.

In this example, a helicon wave plasma source was used as a plasma source.

Moreover, a mixed gas of helium and argon was used. The mixture ratio in concentration ratio was helium gas of 99% and argon gas of 1%, helium gas of 99% and argon gas of 1%, and helium gas of 90% and argon gas of 10%. For comparison, amorphism was also performed by using helium only gas and nitrogen only gas.

A mixed gas of diborane gas diluted with helium gas was used in the doping process.

First, helium plasma was irradiated to the silicon substrate 13. The plasma irradiation was performed in a condition of 1500 W of a source power, 0.9 Pa of pressure, 7 seconds of plasma irradiation time and 75 V, 150 V and 200 V of a bias voltage. After stopping the plasma irradiation and evacuating the vacuum chamber 15, mixed gas plasma of diborane and helium was irradiated without removing the silicon substrate 13 from the vacuum chamber 15. The mixed gas of diborane gas of 5% and helium gas of 95% in concentration ratio was used. The plasma irradiation was performed in a condition of 1000 W of a source power, 2.5 Pa of pressure, 7 seconds of plasma irradiation time and 100 V of a bias voltage. After stopping the plasma irradiation and evacuating the vacuum chamber 15, the vacuum chamber 15 was purged with nitrogen gas and the substrate was removed from the vacuum chamber 15.

In addition, samples which were not subjected to the plasma irradiation for amorphism were prepared for comparison. In other words, mixed gas plasma of diborane and helium was irradiated to the silicon substrate 13 for the first time. The mixed gas of diborane gas of 5% and helium gas of 95% in concentration ratio was used. The plasma irradiation was performed in a condition of 1000 W of a source power, 2.5 Pa of pressure, 7 seconds of plasma irradiation time and 100 V of a bias voltage. After stopping the plasma irradiation and evacuating the vacuum chamber 15 for the first time, the vacuum chamber 15 was purged with nitrogen gas and the substrate was removed from the vacuum chamber 15.

The entire samples were subjected to an RTA treatment at 900° C. for 0 second, and the sheet resistance was measured using a four probe method.

FIG. 16 shows the sheet resistance of p-layer prepared through an experiment where amorphism was performed by irradiating mixed gas plasma of argon and helium, plasma doping was performed by using a mixed gas of diborane and helium, and the resulting substrate were subjected to an RTA treatment, in comparison with that of p-layer prepared through an experiment where amorphism was performed by irradiating helium plasma, plasma doping was performed by using a mixed gas of diborane and helium, and the resulting substrate were subjected to an RTA treatment. In the amorphism by helium plasma irradiation, when the bias voltage was 200 V, the sheet resistance increased compared to the bias voltage of 150 V. To the contrary, in the amorphism by mixed gas plasma irradiation of helium and argon, the sheet resistance decreased as the bias voltage increased. Therefore, it is considered that the sheet resistance can be further reduced by increasing the bias voltage. When the bias voltage of the plasma irradiation for the amorphism was 200 V, the sheet resistance obtained in the case where the amorphism was performed by irradiating mixed gas plasma of helium of 99% and argon of 1% was lower than that obtained in the case where the amorphism was performed by irradiating helium only plasma, even though the thickness of the amorphous layer obtained in the former case was smaller than that of the latter case by 2.8 nm. Therefore, when using mixed gas of helium and argon, the sheet resistance is easily reduced compared with the case of using helium gas.

### EXAMPLE 10

### Amorphism by Plasma Irradiation Using B₂H₆ Gas Severely Diluted with Helium Gas and Plasma Doping

Next, description will be made to the case where boron doping is performed simultaneously with the amorphism.

In the vacuum chamber 15, plasma was irradiated to the silicon substrate as the object 13 to be processed.

In this example, a helicon wave plasma source was used as a plasma source.

Moreover, a mixed gas of helium and diborane was used. The mixture ratio in concentration ratio was changed in a concentration range from helium gas of 95% and diborane gas of 5% to helium gas of 99.975% and diborane gas of 0.025%.

First, helium plasma was irradiated to the silicon substrate 13. The plasma irradiation was performed in a condition of 1500 W of a source power, 0.9 Pa of pressure, 7 seconds, 30 seconds and 60 seconds of plasma irradiation time and 60 V of a bias voltage. After stopping the plasma irradiation and evacuating the vacuum chamber 15 for the first time, the vacuum chamber 15 was purged with nitrogen gas and the substrate was removed from the vacuum chamber 15.

For the entire samples, the thickness of the amorphous layer was measured with an ellipsometry and the optical absorption coefficient with respect to light of 530 nm wavelength was measured. The dose amount of boron was measured by SIMS.

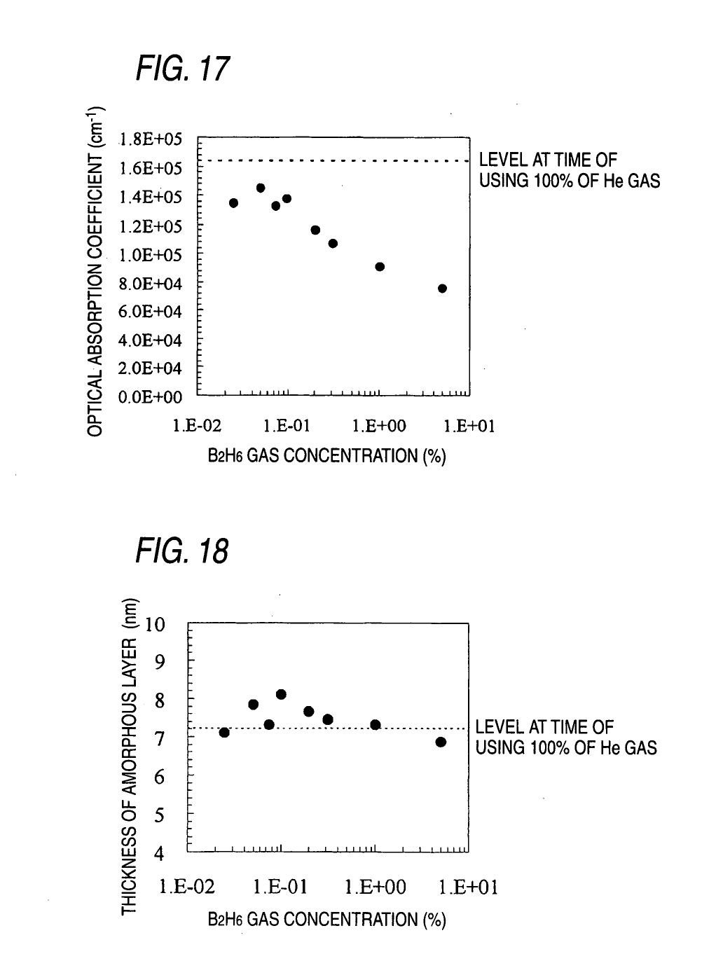

FIG. 17 shows the relation between the concentration of the B₂H₆ gas and the optical absorption coefficient with respect to light of 530 nm wavelength when the plasma doping was performed by changing the ratio of B₂H₆ gas in the mixed gas of B₂H₆ and He. The optical absorption coefficient reached the highest when the amorphism was performed by irradiating He only gas plasma. Moreover, the optical absorption coefficient was not changed much in the concentration range of the mixed gas of B₂H₆ and He, from 0.025%/99.975% (B₂H₆/He) to 0.1%/99.9%. However, when the concentration of the B₂H₆ gas was increased to a level greater than 0.1%, the optical absorption coefficient decreased as the concentration of the B₂H₆ gas increased. For example, the optical absorption coefficient of the amorphous layer which was experimentally prepared with the mixed gas of B₂H₆ of 5% and He of 95% in concentration ratio decreased to a level corresponding to 55% of that obtained with the mixed gas of B₂H₆ of 0.1% and He of 99.9% in concentration ratio and decreased to a level corresponding to 46% of that obtained with the He only gas (i.e., He of 100%). However, it can be seen that the optical absorption coefficient of the amorphous layer obtained even in the case of using the mixed gas of B₂H₆ of 5% and He of 95% in concentration ratio was 6.3 times greater than that obtained in the case of crystalline silicon (c-Si) substrate.

FIG. 18 shows a thickness change of the amorphous layer when the plasma doping was performed by changing the ratio of B₂H₆ gas in the mixed gas of B₂H₆ and He. It can be seen that the thickness of the amorphous layer is substantially the same as that obtained in the case where the amorphism was performed by irradiating He only gas. More specifically, in the case of using mixed gas of B₂H₆ of 0.1% and He of 99.9% in concentration ratio, the thickness of the amorphous layer reached the greatest. However, the thickness of the amorphous layer was likely to decrease as the concentration of the B₂H₆ increased or decreased. In other words, when it is desired to perform the plasma doping simultaneously with the amorphism, it is desirable to mixed B₂H₆ gas with helium gas in a concentration ratio range of between 0.05%/99.95% (B₂H₆/He) and 0.1%/99.9%.

The reason why the optical absorption coefficient decreased when the concentration of the B₂H₆ gas was increased to a level greater than 0.1% even with the same thickness of the amorphous layer is considered to be attributable to decrease in amorphousness. In other words, crystals are likely to be de-crystallized as the concentration of the B₂H₆ gas decreases and the concentration of He increases. Therefore, in order to form an amorphous layer having a high optical absorption coefficient, it is desirable that the concentration of the B₂H₆ gas is lower than 1% and the concentration of helium gas is greater than 99.9%.

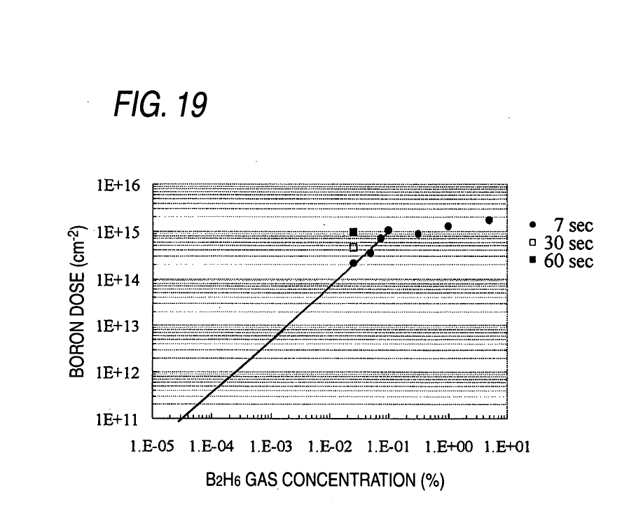

FIG. 19 shows a change in a dose amount of boron when the mixture ratio of B₂H₆ gas and helium gas was changed. When the concentration of the B₂H₆ gas was lower than 0.1%, the dose amount of boron decreased. In the case of the plasma irradiation time of 7 seconds, the relation between the concentration of the B₂H₆ gas and the dose amount of boron was obtained in a B₂H₆ concentration range of between 0.025% and 0.1%. The relation can be expressed by Formula 4, where Z (%) stands for the concentration of the B₂H₆ gas and W (cm⁻²) stands for the dose amount of boron.

W=10¹⁶·Z^{1.1554} [Formula 4]

By extrapolating the relation into a region where the concentration of the B₂H₆ gas is lower than 0.025%, it is possible to calculate the concentration of the B₂H₆ gas required for obtaining a desired dose amount of boron. In other words, when it is desired to use a dose amount of boron greater than 1E14 cm⁻², it is desirable to set the concentration of the B₂H₆ gas to a level greater than 0.02%. Moreover, when it is desired to use a dose amount of boron greater than 1E13 cm⁻², it is desirable to set the concentration of the B₂H₆ gas to a level greater than 0.0026%. Further, when it is desired to use a dose amount of boron greater than 1E12 cm⁻², it is desirable to set the concentration of the B₂H₆ gas to a level greater than 0.00035%. Furthermore, when it is desired to use a dose amount of boron greater than 1E11 cm⁻², it is desirable to set the concentration of the B₂H₆ gas to a level greater than 0.00005%.

In order to increase the dose amount of boron, the plasma irradiation time may be increased. In the case of the plasma irradiation time of 30 seconds, the dose amount was 3 times greater than the case of using 7 seconds of plasma irradiation time. In the case of the plasma irradiation time of 60 seconds, the dose amount was 5 times greater than the case of using 7 seconds of plasma irradiation time. However, since a sputtering is performed at a rate of about 0.08 nm/sec, a 2.4 nm-thick layer of the silicon substrate is removed during 30 seconds of irradiation and a 5 nm-thick layer of the silicon substrate is removed during 60 seconds of irradiation. In view of an influence on devices, it is thought that a small amount of sputtering is good and the irradiation for 30 seconds is too long. Therefore, there is a possibility that the lower concentration limit of the B₂H₆ gas with respect to the lower limit of the desired dose amount is shifted by ⅓ in a direction where the concentration of the B₂H₆ gas is decreased by ⅓. However, the lower concentration limit of the B₂H₆ gas with respect to the lower limit of the desired dose amount is not shifted by more than ⅓. Moreover, since the plasma irradiation is not performed at a stable bias voltage when the plasma irradiation time is short, it is desirable to irradiate the plasma for a period longer than 5 seconds, preferably longer than 7 seconds.

Therefore, in the case where the boron doping is performed simultaneously with the amorphism by irradiating mixed gas plasma of B₂H₆ gas and helium gas, in order to maintain the optical absorption coefficient at a high level, it is desirable to set the concentration of the B₂H₆ gas to a level lower than 0.1%. In order to satisfy the allowable range of the sputtering and secure the dose amount of boron, when it is desired to maintain the dose amount of boron at 1E14 cm⁻², it is desirable to set the concentration of the B₂H₆ gas to a level greater than 0.02%. Moreover, when it is desired to maintain the dose amount of boron at 1E13 cm⁻², it is desirable to set the concentration of the B₂H₆ gas to a level greater than 0.0026%. Further, when it is desired to maintain the dose amount of boron at 1E12 cm⁻², it is desirable to set the concentration of the B₂H₆ gas to a level greater than 0.00035%. Furthermore, when it is desired to maintain the dose amount of boron at 1E11 cm⁻², it is desirable to set the concentration of the B₂H₆ gas to a level greater than 0.00005%.

### EXAMPLE 11

### Junction Depth Control by Controlling Depth of Amorphous Layer Formed by Plasma Irradiation

Next, description will be made to a method of changing the junction depth by changing the depth of the amorphous layer formed by the plasma irradiation.

In the vacuum chamber 15, plasma was irradiated to the silicon substrate as the object 13 to be processed.

In this example, a helicon wave plasma source was used as a plasma source.

Moreover, helium gas was used.

First, helium plasma was irradiated to the silicon substrate 13. An amorphous layer having a different depth of 6.5 nm and 19.5 nm was formed by changing the bias voltage. After stopping the plasma irradiation and evacuating the vacuum chamber 15 for 5 seconds, plasma of B₂H₆ gas diluted with helium gas was irradiated. After stopping the plasma irradiation and evacuating the vacuum chamber 15, the vacuum chamber 15 was purged with nitrogen gas and the substrate was removed from the vacuum chamber 15.

Then, a laser of 0.53 μm wavelength was irradiated to two types of samples for 100 ns. The energy density of the laser was 1500 mJ/cm².

Moreover, SIMS profile of boron was measured with respect to the entire samples.

The junction depth of the sample after the laser annealing was 16.5 nm in the case where the depth of the amorphous layer by the helium plasma irradiation was 6.5 nm. Meanwhile, the junction depth of the sample after the laser annealing was 33 nm in the case where the depth of the amorphous layer by the helium plasma irradiation was 19.5 nm. Since the diffusion coefficient of boron in amorphous portions of the silicon substrate at the time of annealing is greater than that in crystalline portions of the silicon substrate, boron is likely to be deeply diffused as the depth of the amorphous layer before the annealing increases. From this reason, even in the same doping and annealing conditions, it is possible to change the junction depth by changing the depth of the amorphous layer.

### Exemplary Embodiment 4

### Impurity Doping Using Ion Shower Apparatus

Next, description will be made to an impurity doping method using an ion shower apparatus.

When doping impurities, the boron doping may be performed simultaneously with the amorphism by using the ion shower apparatus even though the ion shower apparatus provides a lower level of amorphousness.

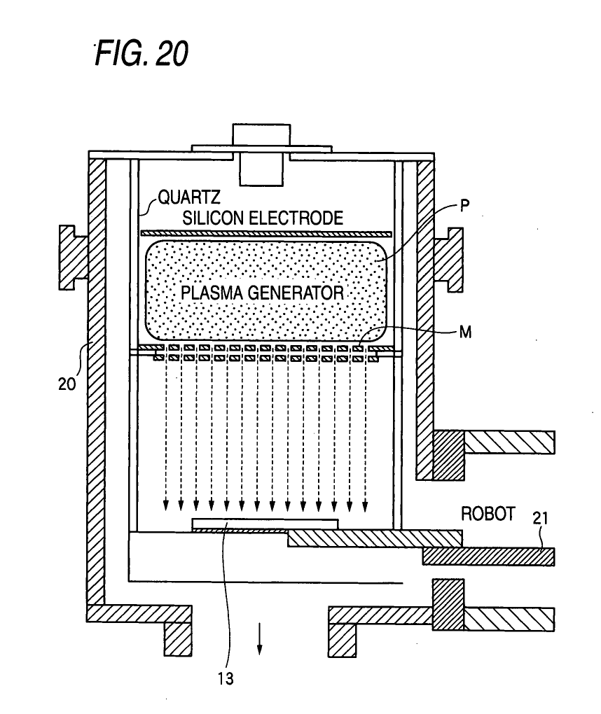

FIG. 20 is a sectional diagram showing an essential part of an ion shower apparatus used in a fourth exemplary embodiment of the invention. The apparatus includes a plasma generating unit P in a chamber 20. Ions are pulled out from plasma generated in the plasma generating unit P through a mesh M (in this example, silicon grid), whereby the ions are irradiated (ion shower) to the surface of the solid base body as the substrate 13 to be processed. In other words, the ions are pulled out from the plasma by a voltage applied to the mesh M so as to be irradiated to the solid base body.

In the case of plasma, radicals and gases as well as the ions are collided into the solid base body. Meanwhile, in the ion shower method, only ions are collided into the solid base body. The amount of substance colliding to the solid base body in a unit time in the case of directly irradiating the plasma is greater than that obtained in the ion shower method. Therefore, the amorphousness in the ion shower method decreases compared with the case of a direct plasma irradiation method. However, since mass spectrometry is not performed, the amount of ions colliding to the solid base body is greater than that obtained in the ion shower method.

From the above-mentioned point, even in the case of using the ion shower method, it is possible to realize shallow amorphism by using elements having small atomic weight such as helium. Moreover, it is also possible to realize the amorphism by using the rare gases disclosed in the invention and perform the boron doping simultaneously with the amorphism.

### INDUSTRIAL APPLICABILITY

As described above, according to the invention, since it is possible to form shallow junction with high precision, it is effectively applied to micro devices. Moreover, since it is possible to define the formation area to a finer range, the invention can be applied to a still finer device such as quantum devices.

1-30. (canceled)

31. A method of introducing impurity comprising:
a first step of making a surface of a semiconductor layer to be amorphous by reacting plasma composed of particles which are electrically inactive in the semiconductor layer to a surface of a solid base body including the semiconductor layer; and
a second step of introducing impurity to the surface of the solid base body;
wherein after performing the first step, by performing the second step, an amorphous layer with fine pores is formed on the surface of the solid base body including the semiconductor layer, and impurity are introduced in the amorphous layer to form an impurity introducing layer.

32. The method of introducing impurity according to claim 31, wherein the first step is a step of irradiating the plasma to the surface of the semiconductor layer.

33. The method of introducing impurity according to claim 31, wherein the first step is a step of irradiating ions to the surface of the semiconductor layer by introducing the plasma to the surface of the semiconductor layer through a mesh.

34. The method of introducing impurity according to claim 31, wherein after performing the second step, by performing the first step, impurity are introduced to the surface of the solid base body including the semiconductor layer to form an impurity introducing layer, and the plasma composed of particles which are electrically inactive in the semiconductor layer is irradiated to the impurity introducing layer to form an amorphous layer.

35. A method of introducing impurity, comprising:
a first step of making a surface of a semiconductor layer to be amorphous by reacting plasma composed of particles which are electrically inactive in the semiconductor layer to a surface of a solid base body including the semiconductor layer; and
a second step of introducing impurity to the surface of the solid base body;
wherein the second step is performed at the same time as performing the first step;
in the second step, plasma in which those impurities electrically active in the semiconductor layer are diluted with helium is irradiated to the surface of the solid base body.

36. The method of introducing impurity according to claim 31, wherein the diameter of the pores is smaller than 8 nm.

37. The method of introducing impurity according to claim 31, further comprising an annealing step after the first step and the second step, wherein the annealing step is a step of electrically activating the impurity.

38. The method of introducing impurity according to claim 31, wherein the first step is a step of forming an amorphous layer to a depth of 19 nm or less.

39. The method of introducing impurity according to claim 31, wherein the first step is a step of forming an amorphous layer to a depth of 5 nm or more.

40. The method of introducing impurity according to claim 31, wherein the second step is a step of plasma-doping the impurity.

41. The method of introducing impurity according to claim 31, wherein the second step is a step of supplying impurity ions from the plasma through the mesh.

42. The method of introducing impurity according to claim 31, wherein the second step is a step of ion-implanting the impurity.

43. The method of introducing impurity according to claim 31, wherein the second step is a step of gas-doping the impurity.

44. The method of introducing impurity according to claim 39, wherein the first and second steps are performed in the same process chamber as a sequential process in-situ.

45. The method of introducing impurity according to claim 35, wherein the first step is performed simultaneously with the second step, and the first step includes a step of irradiating the plasma including helium gas having a concentration range of between 99% and 99.999%.

46. The method of introducing impurity according to claim 32, wherein the first step includes a step of forming an amorphous layer to a depth X represented by the following formula:
1(1/0.481)·In(Y/121.37)<X<(Y/270.87)^{-(1.2684)},
where Y (in unit of ‘u’) stands for an atomic weight of elements constituting the amorphous layer and X (in unit of ‘nm’) stands for the depth of the amorphous layer.

47. The method of introducing impurity according to claim 35, wherein the first step and the second step are performed at the same time, and the method includes a step of forming the impurity introducing layer by the plasma in which those impurities electrically active in the semiconductor layer are diluted with helium by irradiating the He plasma including B₂H₆ gas having a concentration range of between 0.001% and 1.0%.
